(19) United States
(12) Patent Application Publication
(10) Pub. No.: US 2005/0155752 A1
(43) Pub. Date: Jul. 21, 2005

(54) Thermal interface and method of making the same

(76) Inventors: Ralph I. Larson, Bolton, MA (US); Robert J. Proulx, Worcester, MA (US)

Correspondence Address: DALY, CROWLEY, MOFFORD & DURKEE, LLP, SUITE 301A, 354A TURNPIKE STREET, CANTON, MA, 02021-2714, US

(21) Appl. No.: 10/994,194

(22) Filed: Nov. 19, 2004

Related U.S. Application Data
(60) Provisional application No. 60/523,260, filed on Nov. 19, 2003.

(51) Int. Cl. H05K 7/20

(52) U.S. Cl. 165/185

(57) ABSTRACT

A thermal interface material and methods for preparing the same are disclosed. The thermal interface material comprises a copper mesh and a slurry. The copper mesh is impregnated and coated with the slurry. The slurry comprises a liquid metal alloy mixed with a plurality of thermal conductive particles. The methods include methods for preparing the thermal interface material, preparing the slurry, preparing the mesh, preparing the device for receiving the material, and for applying the thermal interface to the device.

### CROSS REFERENCE TO RELATED APPLICATIONS

This application claims the benefit under 35 U.S.C. § 119(e) of U.S. Provisional Application No. 60/523,260 filed Nov. 19, 2003; the disclosure of which is hereby incorporated by reference herein in its entirety.

### STATEMENT REGARDING FEDERALLY SPONSORED RESEARCH

Not applicable.

### FIELD OF THE INVENTION

The present invention relates generally to a thermal interface and more particularly to a thermal interface between an integrated circuit and a heat sink.

### BACKGROUND OF THE INVENTION

As is known in the art, there is a trend to reduce the size of semiconductor devices, integrated circuits and microcircuit modules while at the same time having the devices, circuits and modules perform more functions. To achieve this size reduction and increased functionality, it is necessary to include a greater number of active circuits, such as transistors for example, in a given unit area. As a consequence of this increased functionality and dense packaging of active devices, such devices, circuits and modules (hereinafter collectively referred to as “circuits”) use increasingly more power. Such power is typically dissipated as heat generated by the circuits.

This increased heat generation coupled with the need for circuits to have increasingly smaller sizes has led to an increase in the amount of heat generated in a given unit area. To further exacerbate the problem, the circuits are often densely mounted on printed circuit boards.

This increase in the amount of heat generated in a given unit area has led to a demand to increase the rate at which heat is transferred away from the circuits in order to prevent the circuits from becoming damaged or destroyed due to exposure to excessive heat. To increase the amount of heat which such circuits can withstand, the circuits can include internal heat pathways which channel or otherwise direct heat away from the most heat-sensitive regions of the circuits.

Although this internal heat pathway technique increases the amount of heat which the circuits can withstand while still operating, one problem with this internal heat pathway technique is that the amount of heat generated by the circuits themselves often can exceed the amount of self-generated heat which the circuits can successfully expel as they are caused to operate at higher powers. Furthermore, other heat generating circuit components mounted on printed circuit boards proximate the circuits of interest further increase the difficulty with which heat can be removed from heat sensitive circuits. Thus, to increase the rate at which heat is transferred away from the circuits, a heatsink is typically attached to the circuits.

Such heatsinks typically include a base from which project fins or pins. The fins or pins are typically provided by metal extrusion, stamping or other mechanical manufacturing techniques. The heatsinks conduct and radiate heat away from the circuits. To further promote the heat removal process, fans are typically disposed adjacent the heatsink to blow or otherwise force air or gas through and around the fins or pins of the heatsink.

In order to provide maximum heat removal from the device by the heatsink, the heat sink must be in contact with the device. One of the properties of a device that detracts from the ability to have heat removed therefrom by way of a heatsink has to do with the flatness of the surface of the device to which the heatsink is attached. Any non-linear surface variations result in the heat sink not making direct contact along the entire surface of the device, which directly affects the amount of heat the heatsink can remove from the device.

### SUMMARY OF THE INVENTION

A thermal interface and methods for preparing the same are presented. The thermal interface comprises a copper mesh and a slurry. The copper mesh is impregnated and coated with the slurry. The slurry comprises a liquid metal alloy mixed with a plurality of thermally conductive particles. The methods include methods for preparing the thermal interface material, preparing the slurry, preparing the mesh, preparing the device for receiving the material, and for applying the thermal interface to the device.

In accordance with the present invention, a thermal interface comprises a conductive mesh and a slurry, having the characteristics of a non-eutectic solder joint, impregnated within the conductive mesh. With this particular arrangement, a thermal interface which improves heat removal from a heat-generating device by a heatsink is provided. The mesh/slurry thermal interface fills voids or spaces between the heat-generating device and an applied heatsink. Such voids or spaces can result, for example, from non-linearities in surfaces of the heat sink and/or the heat-generating device. By filling the voids or spaces between the heat generating device and an applied heatsink, the thermal interface improves the amount of heat the heatsink can remove from the heat-generating device. In one embodiment, the slurry comprises a liquid metal alloy and a plurality of thermally conductive particles mixed with said liquid metal alloy. In one particular embodiment, the thermally conductive particles are provided as a powder fill which comprises in the range of about 20%-70% by volume of the slurry and the conductive mesh is provided as a conductive wire mesh having in the range of about 25 to about 200 wires per inch with each of the wires having a diameter in the range of about 0.0005 inch to about 0.006 inch. The conductive wire mesh is impregnated with the slurry and the slurry is disposed on each of first and second opposing surfaces of the conductive wire mesh.

In accordance with a further aspect of the present invention, a method of preparing a thermal interface comprises mixing a liquid metal alloy and a plurality of thermally conductive particles to provide a slurry having the characteristics of a non-eutectic solder joint and impregnating and coating a conductive mesh with the slurry. With this particular technique, a thermal interface is provided. In one embodiment, the liquid metal alloy is provided a an alloy of 61% Gallium, 25% Indium, 13% tin and 1% zinc and the thermally conductive particles correspond to silver particles with the silver particles having a size of approximately 25 μm.

In accordance with a still further aspect of the present invention, a method of preparing a slurry includes placing a predetermined amount of a liquid metal alloy into a mixing vessel, adding approximately 40% by volume of thermally conductive particles to the liquid metal alloy and mixing the liquid metal alloy with the thermally conductive particles until the thermally conductive particles are absorbed by the liquid metal alloy to provide a slurry having the characteristics of a non-eutectic solder joint. In one embodiment, the liquid metal alloy comprises 61% Gallium, 25% Indium, 13% tin and 1% zinc and the thermally conductive particles correspond to silver particles having a size of approximately 25 μm.

In accordance with a still further aspect of the present invention, a method of preparing a surface to receive a thermal interface includes cleaning and drying the surface, applying a predetermined amount of cleaner to the surface, wiping the cleaner off the surface, applying a predetermined amount of a liquid metal alloy to the surface, and rubbing the liquid metal alloy into the surface until the surface is covered with a layer of the liquid metal alloy. In one embodiment, the cleaner includes bleach, a base, a detergent and water and the liquid metal alloy comprises 61% Gallium, 25% Indium, 13% tin and 1% zinc.

In accordance with a still further aspect of the present invention, a method of impregnating a mesh includes adding said a conductive mesh to a vessel having a slurry disposed therein with the slurry comprising a liquid metal alloy and thermally conductive particles, rubbing the slurry into the mesh until the mesh is impregnated and coated with the slurry and removing excess slurry from the mesh. In one embodiment, the conductive mesh is provided as a copper mesh having approximately 100 wires per inch with each of the wires having a diameter of approximately 0.0022 inches and the slurry comprises a liquid metal alloy comprising 61% Gallium, 25% Indium, 13% tin and 1% zinc, and 40% by volume of silver particles having a size of approximately 25 μm.

In accordance with a still further aspect of the present invention, a method for applying a thermal interface to a surface of a device includes placing a thermal interface on a prepared surface of the device, with the thermal interface comprising a conductive mesh having a slurry impregnated therein and coating upper and lower surfaces of the mesh with the slurry having the characteristics of a non-eutectic solder joint and applying pressure to the thermal interface to remove air bubbles from between the device and the thermal interface. In one embodiment, the conductive mesh is provided as a copper mesh having approximately 100 wires per inch with each of the wires having a diameter of approximately 0.0022 inches and approximately 30 pounds per square inch of pressure are applied to the thermal interface.

A heatsink assembly includes a heatsink and a thermal interface disposed on a surface of said heatsink, with the thermal interface including a conductive mesh and a slurry, having the characteristics of a non-eutectic solder joint, impregnated within the conductive mesh. With this particular arrangement, a heat sink which can rapidly remove heat from a heat-generating device provided. The heatsink assembly can correspond to a fan heatsink. In one particular embodiment, the thermally conductive particles are provided as a powder fill which comprises in the range of about 20%-70% by volume of the slurry and the conductive mesh is provided as a conductive wire mesh having in the range of about 25 to about 200 wires per inch with each of the wires having a diameter in the range of about 0.0005 inch to about 0.006 inch. The conductive wire mesh is impregnated with the slurry and the slurry is disposed on each of first and second opposing surfaces of the conductive wire mesh. The mesh/slurry thermal interface fills voids or spaces between the heat-generating device and an applied heatsink. Such voids or spaces can result, for example, from non-linearities in surfaces of the heat sink and/or the heat-generating device. By filling the voids or spaces between the heat generating device and an applied heatsink, the thermal interface improves the amount of heat the heatsink can remove from the heat-generating device. In one embodiment, the slurry comprises a liquid metal alloy of 61% Gallium, 25% Indium, 13% tin and 1% zinc and 40% by volume of silver particles having a size of approximately 25 μm and the conductive mesh is provided as a copper mesh having approximately 100 wires per inch with each of the wires having a diameter of approximately 0.0022 inches.

An integrated circuit assembly comprising an integrated circuit and a thermal interface disposed on a surface of the integrated circuit, with the thermal interface provided from a conductive mesh and a slurry having the characteristics of a non-eutectic solder joint, impregnated within the conductive mesh. With this particular arrangement, an integrated circuit assembly having a surface through which heat can be rapidly removed is provided. In one particular embodiment, the slurry is provided from a liquid metal alloy and a plurality of thermally conductive particles mixed with said liquid metal alloy. In one embodiment, the thermally conductive particles are provided as a powder fill which comprises in the range of about 20%-70% by volume of the slurry and the conductive mesh is provided as a conductive wire mesh having in the range of about 25 to about 200 wires per inch with each of the wires having a diameter in the range of about 0.0005 inch to about 0.006 inch. The conductive wire mesh is impregnated with the slurry and the slurry is disposed on each of first and second opposing surfaces of the conductive wire mesh. The mesh/slurry thermal interface fills voids or spaces between the heat-generating device and an applied heatsink. Such voids or spaces can result, for example, from non-linearities in surfaces of the heat sink and/or the heat-generating device. By filling the voids or spaces between the heat generating device and an applied heatsink, the thermal interface improves the amount of heat the heatsink can remove from the heat-generating device. In one embodiment, the slurry comprises a liquid metal alloy of 61% Gallium, 25% Indium, 13% tin and 1% zinc and 40% by volume of silver particles having a size of approximately 25 μm and the conductive mesh is provided as a copper mesh having approximately 100 wires per inch with each of the wires having a diameter of approximately 0.0022 inches.

### BRIEF DESCRIPTION OF THE DRAWINGS

The foregoing features of this invention, as well as the invention itself, may be more fully understood from the following description of the drawings in which:

FIG. 1 is a side view of integrated circuit and a heat sink having the thermal interface of the present invention included therewith;

FIG. 2 is a perspective view of the mesh and slurry comprising the thermal interface of the present invention;

FIG. 3 is a flow chart of the method of applying a thermal interface to a device;

FIG. 4 is a flow chart of the process for preparing the slurry;

FIG. 5 is a flow chart of the process for impregnating the mesh with the slurry;

FIG. 6 is a flow chart of the process for preparing the surface of the device receiving the thermal interface; and

FIG. 7 is a flow chart for applying the thermal interface to the device.

### DETAILED DESCRIPTION OF THE INVENTION

A thermal interface comprising a mesh impregnated with a slurry of liquid metal and thermally conductive particles is used to provide optimal thermal conductivity between a device such as an integrated circuit (IC) and a heat sink.

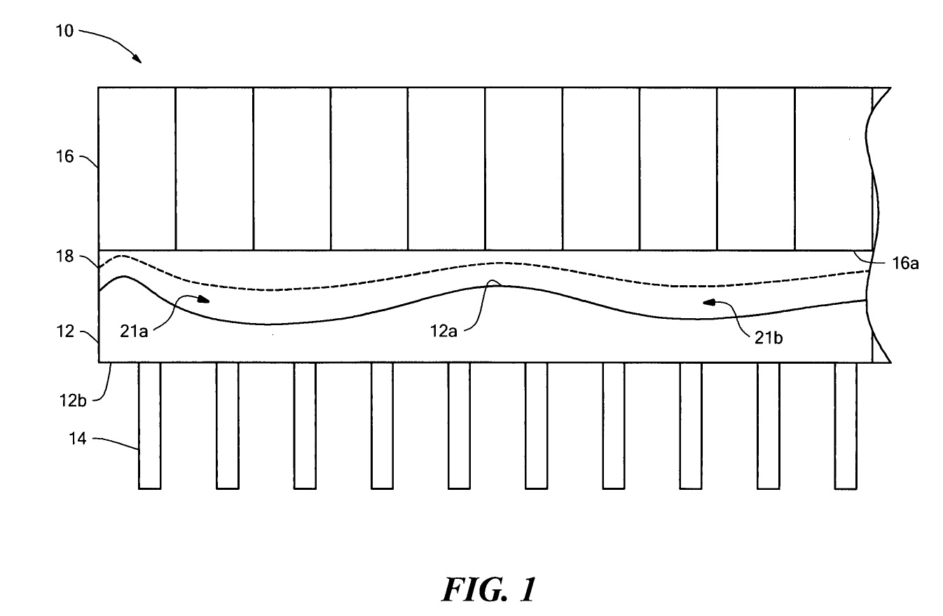

Referring to FIG. 1 an assembly 10 includes an integrated circuit (IC) or other heat generating device 12 having first and second opposing surfaces 12a, 12b and pins 14 projecting from the surface 12b and a heatsink 16 having a thermal interface 18 disposed between a surface of the heatsink and a surface of the IC. The surface 12a of the IC 12 is non-linear. While the non-linearity here is exaggerated to help illustrate one problem solved by the present invention, even nonlinearity on the order of three thousandths of an inch can be a significant problem when it comes to removing heat from the device 12. It should be appreciated that while only the device 12 is shown having a nonlinear surface, the surface of the heatsink 16 may also be nonlinear. Thus, either or both of the IC (or other heat generating device) and the heatsink can have nonlinear surfaces.

Regardless of where the non-linear surfaces occur, suffice it to say that without the thermal interface, surfaces of the heatsink would be disposed directly against the surface 12a of the IC and due to the nonlinearity of the surfaces (e.g. surface 12a in the example shown in FIG. 1), the heat sink would not make contact with the entire top surface of the device 12, resulting in an air gap between certain parts of the device surface and the bottom surface of the heatsink. For example, without interface 18, air gaps may be present in at least regions 21a, 21b shown in FIG. 1. The presence of any air gaps between the surface of the heat sink 16 and the surface 12a of the heat generating device 12 reduces the amount of heat which the heatsink can conduct away from the IC.

As shown in FIG. 1, the thermal interface material 18 is disposed between the device surface 12a and the surface 16a of the heatsink 16. The thermal interface 18 comprises a liquid slurry and a mesh. The slurry covers the top surface of the device 12, and, since the slurry is A Non-Newtonian Fluid, the slurry flows into and fills any air gaps that would have otherwise resulted.

Thus, the slurry/mesh combination provides an interface 18 which allows changes in volume in local areas of the interface to occur so that the slurry can migrate into gap areas without degrading thermal performance of the interface 18. The mesh retains the liquid slurry such that the slurry does not leak from the space between the device 12 and the heatsink 16. In FIG. 1, the thermal interface 18 is shown to cover the entire surface 12a of the device 12, Broadly speaking, the nature of a non-Newtonian fluid is that it has some of the characteristics of a liquid and some of the characteristics of a solid. More specifically, this material retains its shape until a critical level of force is applied, due to the high capillary attraction between the solid powder and the liquid metal in the interstitial spaces of the powder of the material. This results in an increased heat flow between the device 12 and the heatsink 16 (compared with the heat flow which occurs without the thermal interface), despite the presence of non-linearities in the surface of the device 12. Although the thermal interface 18 in FIG. 1 is shown disposed over the entire surface of the device, in other embodiments, it may be desirable or even necessary for the thermal interface 18 to contact only a portion of the heat sink 16 and/or the device 26.

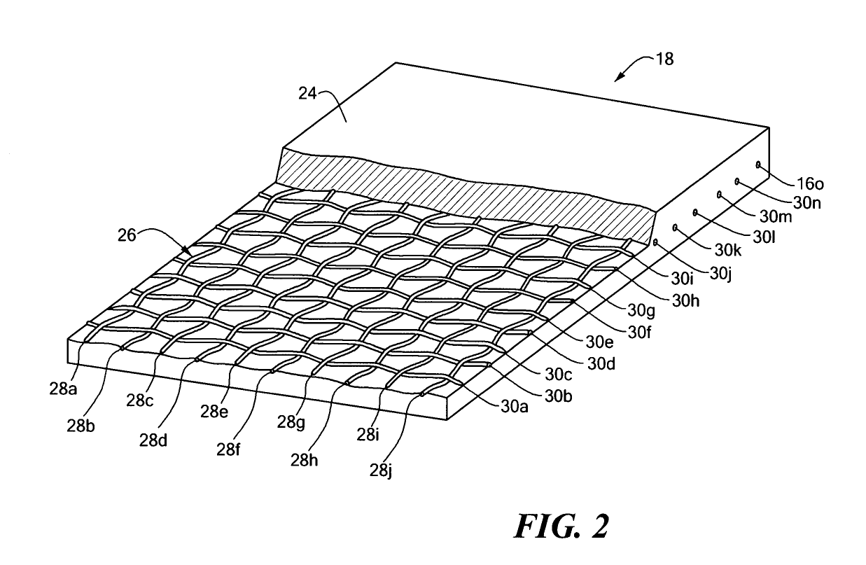

Referring now to FIG. 2, the thermal interface 18 includes a liquid metal material 24 having disposed therein a wire mesh 26 comprised of warp wires 28a-28j and weft wires 30a-30o. A portion of the liquid metal material 24 has been removed to reveal a portion of the mesh 13.

The liquid metal material, also referred to as a slurry, is comprised of a liquid metal alloy having thermally conductive particles mixed therein. In a preferred embodiment, the thermally conductive particles are comprised of silver powder. The silver powder acts to hold the liquid metal in place, yet conform to the non-uniformities and out-of-flatness of the two surfaces. The silver powder also acts a wetted filler with the copper mesh.

Preferably the liquid metal alloy is a quaternary alloy although other alloys, such as tertiary alloys, could also be used. In a preferred embodiment the liquid metal alloy is comprised of a mixture of 61% Gallium, 25% Indium, 13% Tin and 1% Zinc. Such a liquid metal alloy is available from Indium Corporation of America in Utica, N.Y., and has a part number of 05876.

The silver powder has a generally uniform size. In a preferred embodiment a silver powder having a particle size of approximately 25 μm is used. Such a silver powder is available from Ferro Corporation of South Plainfield, N.J. as silver powder Number 11000-02. Alternately, other powders having different particles sizes could be used, as could a combination of different types of powders having the same or different particle sizes. For example, using two powders having different particle sizes (e.g. 8 μm and 25 μm particle sizes) may result in a material having a higher packing density than using a single material having a single particle size (e.g. 25 mm particle size). This is because smaller particles may fill in spaces (within the mesh and between the heat sink and device) left by the joining of larger particles. Thus the present invention encompasses the mixing of different types of powder having the same particle sizes as well as the mixing of the same types of powder having different particle sizes. Any number of material types (e.g. 2-10 different material types) and any number of different particle sizes (e.g. 2 to 10 different particle sizes) may be used.

The slurry is formed by mixing a predetermined amount of silver powder with a predetermined amount of the liquid metal alloy. It is sometimes relatively difficult to get the silver powder to wet to the liquid metal alloy, therefore the following steps can be performed to provide the slurry. In one particular embodiment in which the thermal interface is used with a heat generating device having a surface area of about 10 square centimeters, between 3-10 grams of liquid metal alloy are placed in a mortar. Between 30% and 50% (most preferably 40%) of silver powder is added to the liquid metal alloy. The material is mixed together in the mortar with a pestle to form the slurry. The powder should be mixed such that all the powder is absorbed into the liquid metal alloy, such that the slurry has a common consistency and there are no pockets of unmixed silver powder. The look of the slurry will reflect the fact that the silver powder has been bound with the liquid metal alloy, as would be known to one of ordinary skill in the art.

For operation with a device having a surface flatness of about +/−3.5 mils over a distance of about 31 mm, in either x or y direction the mesh 26 is preferably provided as a copper mesh having 100 wires per square inch and a thickness of 0.0022 inches. Such a mesh is available from TWP of Berkeley, Calif., part number 100X100C022. The mesh may also be comprised of other metals including but not limited to silver, plated aluminum, zinc or from polyester felt having copper fibers embedded therein with nickel plated on the top of the felt. The particular material from which to provide the mesh 26 will depend upon a variety of factors including but not limited to cost, strength, flexibility, thermal conductivity, ease of manipulating/manufacturing and the alloying characteristics of all of the materials involved, including the materials from which the mesh, heatsink, slurry and device are made. Also, other sizes of mesh, including but not limited to a mesh comprised of wires having diameters typically of about 0.0045 inch, can also be used. It should be appreciated that the particular thickness to use in any particular application will depend upon a variety of factors including but not limited to the unevenness of the surface of a device to which a heat sink will be attached, the unevenness of a surface of a heat sink which will be disposed against a device, as well as the physical dimensions and area of the interface joint, and the desired thermal conductivity of the joint.

In one embodiment, a thermal interface manufactured with the above-identified materials has a thermal conductance performance characteristic (typical units are watts/(deg. C×cm²)” which is about five times better than commercially available thermal grease. In summary, considering only thermal performance characteristics, in any given application, the mesh and slurry materials are selected to provide the highest thermal conductivity possible for that application.

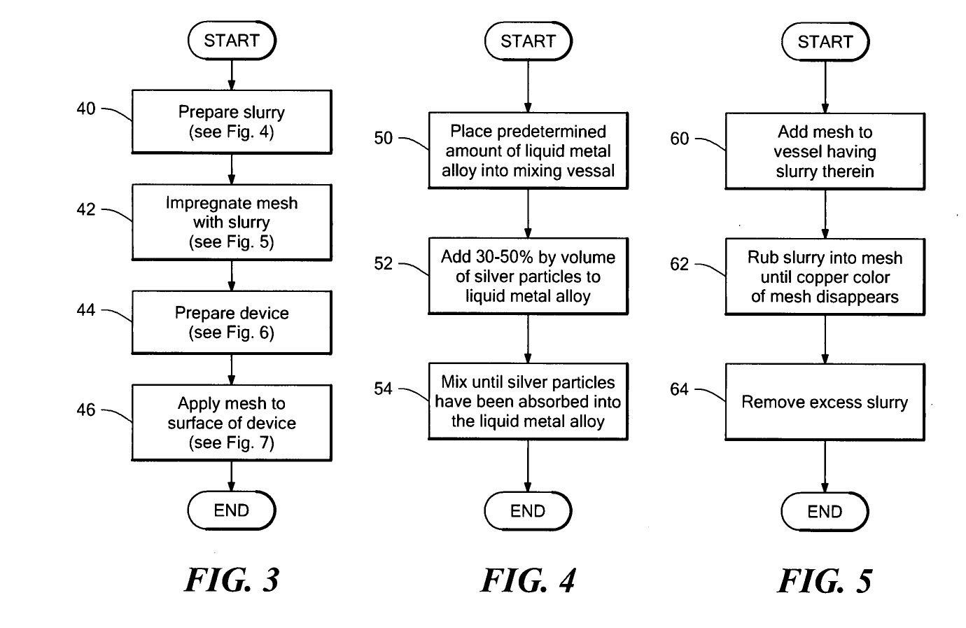

Flow charts of the presently disclosed techniques are depicted in FIGS. 3-7. The rectangular elements are herein denoted “processing blocks” and the diamond shaped elements are herein denoted “decision blocks”. It will be appreciated by those of ordinary skill in the art that unless otherwise indicated herein, the particular sequence of steps described is illustrative only and can be varied without departing from the spirit of the invention. Thus, unless otherwise stated the steps described below are unordered meaning that, when possible, the steps can be performed in any convenient or desirable order.

Referring now to FIG. 3, a method for forming a thermal interface and applying the thermal interface to a device is shown. The process begins in processing block 40 in which the slurry is prepared. The slurry comprises a liquid metal alloy having thermally conductive particles mixed therein. The details of slurry preparation will be discussed below in conjunction with FIG. 4. Briefly, however, in one embodiment, a silver powder (e.g. a silver powder of the type described above) is mixed with a liquid metal (e.g. a liquid metal of the type described above). Because Ga In does not alloy well into silver, the mixture maintains its consistency as a slurry. The purpose of making the slurry is to provide a non-eutectic solder joint. That is, it is desired to provide a mixture which substantially duplicates the liquid phase-solid phase characteristic of a conventional non-eutectic solder joint. During this slurry preparation process, care should be taken not to allow any free floating liquid metal. The slurry acts as a porous sponge and holds the liquid metal therein so that it can be disposed in a desired region as will be clear from the description provided herein below. It should be appreciated the liquid metal wets to the silver but does not amalgamate into it.

In processing block 42 the mesh is impregnated with the slurry. The slurry also coats a top surface of the mesh and a bottom surface of the mesh, resulting in the mesh being disposed within and immediately around the slurry (i.e. the slurry is not completely contained within the mesh per se).

Processing continues with processing block 44 in which the device is prepared to receive the thermal interface. The surface of either the heatsink or the IC device is cleaned and dried. A small amount of the liquid metal alloy is rubbed into the surface to wet the surface and allow for the desired thermal conduction between the device and the thermal interface material.

In processing block 46 the thermal interface is applied to the surface of the device. Processing then ends.

Referring now to FIG. 4, preparing the slurry includes placing a predetermined amount of liquid metal alloy into in a mixing vessel such as a mortar as shown in processing block 50.

In processing block 52, a predetermined amount of thermally conductive particles are added to the liquid metal alloy. The thermally conductive particles are preferably silver particles and the predetermined amount is typically between about 30% and about 50% by volume, most preferably about 40% by volume. It should be appreciated that if a relatively high percentage of silver powder is used, then the resultant slurry has a relatively thick and pasty consistency. On the other hand, if a relatively low percentage of silver power is used, then the resultant slurry has a relatively thin, runny consistency. Ideally, the amount of silver powder added results in a slurry which has a consistency which is neither too thick nor too thin and a desired consistency can be determined empirically. The slurry is preferably provided having a paste-like or thixotropic consistency which should not slump, flow or leak liquid metal under the force of gravity. It should be understood that processing blocks 50 and 52 can be performed in any order.

After the liquid metal alloy and thermally conductive particles are placed in the mixing vessel, as shown in processing block 54 the particles are mixed into the liquid metal alloy until the particles have been absorbed by the liquid metal alloy. The materials are mixed until the mixture has a common consistency which does not include any “pockets” (i.e. unabsorbed portions) of silver powder. One of ordinary skill in the art will know (e.g. by visually inspecting the mixture) whether all of the silver has been absorbed.

It should be appreciated that, ideally, the above-described process results in a slurry which remains paste-like for an indefinite period of time. This results in a slurry having a high yield (ideally a 100% yield).

Referring now to FIG. 5, a process for impregnating a mesh with a slurry includes adding a mesh into a slurry which has been prepared previously (e.g. in accordance with the process of FIG. 4) as shown in processing block 60. The mesh may be cut to the desired size before or after the mesh is added into the slurry.

In processing block 62 the slurry is rubbed into the mesh until the mesh is impregnated with the slurry, and the top and bottom surfaces of the mesh are coated with the slurry. One indication that the mesh is impregnated with the slurry is that the original color of the mesh is no longer visible (e.g. upon unaided visual inspection). Ideally, all voids in the mesh are filled and both surfaces of the mesh have at least some slurry disposed therein.

Processing continues as shown in processing block 64 where excess slurry material is removed. The removal may be done by scraping or any other suitable technique now known or unknown to one of ordinary skill in the art. Processing then ends.

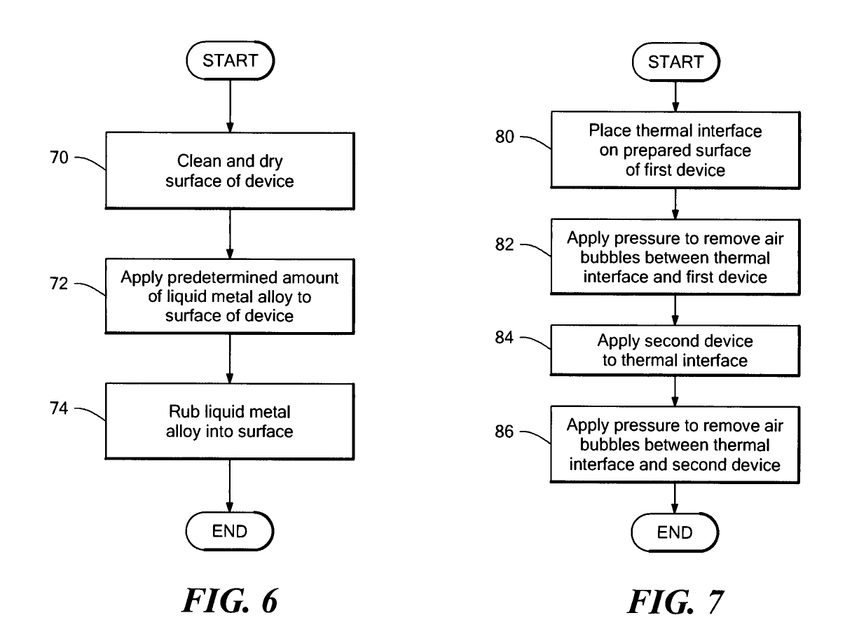

Referring now to FIG. 6, a process for preparing a device to receive a thermal interface of the type described above in conjunction with FIGS. 1 and 2 includes cleaning and drying a surface of the device as shown in processing block 70. This is done to remove any contaminants that may be on the surface of the device and to generally ensure that the surfaces to which the thermal interface will be in contact are physically clean. The cleaner may, for example, be provided from a combination of sodium hypochlorite, sodium hydroxide (a base material) and sodium lauryl sulfonate (a surfactant) and water. The cleaner may, for example, be provided as a combination of bleach, a base, a detergent and water. The bleach based cleaner is wiped off, leaving a clean and dry surface.

As shown in processing block 72, a predetermined amount of the liquid metal alloy is applied to the surface of the device. This aids in wetting of the thermal interface to the surface. One of ordinary skill in the art will recognize when the liquid metal has wet. In general, however, it is desirable for the liquid metal to wet to the surface such that the surface appears shiny due to the presence of a relatively thin (e.g. 1-2 mil thick) film of material on the surface. Preferably, the film should not have a consistency which could be characterized as runny.

In processing block 74, the liquid metal alloy is rubbed into the surface of the device. This results in a thin coating of the liquid metal alloy covering the surface of the device so that the device has an affinity for the thermal interface. The process then ends.

It should be understood that the surface preparation process of FIG. 6 is preferably performed on each surface which will be in contact with the thermal interface material. This may include, for example, a surface of the device or circuit as well as a surface of a heatsink which will be coupled (thermally or mechanically) to the device or circuit (i.e. the process is done for each surface to be attached to either side of the thermal interface).

It should be appreciated that in the case where a first party sells a heatsink having a thermal interface attached thereto, then that party will perform the cleaning process for the heatsink (i.e. so that the thermal interface can be attached to it) and a second party who purchases the heatsink having the thermal interface attached thereto (the combination of the heatsink with an attached thermal interface being referred to herein as a heatsink assembly) would perform the process of FIG. 6 to the device (e.g. an IC, circuit, etc . . . ) before applying the thermal interface (i.e. the heatsink assembly) to the device.

Referring now to FIG. 7, the process for applying the thermal interface to a device

Referring now to FIG. 7, the process for applying the thermal interface to a device placing the thermal interface on a prepared surface of the device as shown in processing block 80.

In processing block 82 pressure is applied to remove air pockets that may be trapped between the thermal interface and the surface of the device. Pressure is applied to either the device or the heatsink or both, depending on the specific configuration of the parts. The amount of pressure applied need only be sufficient to remove any air pockets. Generally, a pressure of approximately 30 pounds per square inch (p.s.i.) is sufficient to remove air pockets.

In processing block 84 the second device, which also has a prepared surface, is applied to the thermal interface which is attached to the first device. The first device may be an IC and the second device a heatsink, or the first device could be a heatsink and the second device an IC. In a preferred embodiment, the thermal interface is first applied to a heatsink and then the heatsink is applied to the second device.

In processing block 86 pressure is applied to remove air bubbles between the second device and the thermal interface. In one exemplary embodiment, a pneumatic cylinder equipped with a foot to span and interdigitate the heat sink is pressurized with air to effect the mechanical force of approximately 30 pounds per square inch of pressure is applied. The process then ends.

Having described preferred embodiments of the invention it will now become apparent to those of ordinary skill in the art that other embodiments incorporating these concepts may be used. Accordingly, it is submitted that that the invention should not be limited to the described embodiments but rather should be limited only by the spirit and scope of the appended claims.

1. A thermal interface comprising:
a conductive mesh; and
a slurry, having the characteristics of a non-eutectic solder joint, impregnated within said conductive mesh with said slurry.

2. The thermal interface of claim 1 wherein said slurry comprises:
a liquid metal alloy;
a plurality of thermally conductive particles mixed with said liquid metal alloy.

3. The thermal interface of claim 1 wherein said liquid metal wets to said thermally conductive particles but does not amalgamate into it such that said slurry is provided having the characteristics of a non-eutectic solder joint.

4. The thermal interface of claim 3 wherein:
said slurry comprises:
a liquid metal alloy; and
a powder fill in the range of about 20%-70% by volume; and
said conductive mesh comprises a conductive wire mesh having in the range of about 25 to about 200 wires per inch and having first and second opposing surfaces, each of said wires having a diameter in the range of about 0.0005 inch to about 0.006 inch with said conductive wire mesh being impregnated with said slurry and said slurry being disposed each of the first and second surfaces of said conductive wire mesh.

5. The thermal interface of claim 3 wherein said liquid metal alloy comprises 61% Gallium, 25% Indium, 13% tin and 1% zinc.

6. The thermal interface of claim 5 wherein said thermally conductive particles are provided as a powder fill which comprises about 40% by volume of said slurry.

7. The thermal interface of claim 6 wherein said powder fill comprises silver particles having a size of approximately 25 μm.

8. The thermal interface of claim 5 wherein said liquid metal alloy is provided as a metallic alloy having a melting temperature in the range of about 0 deg C. to about 150 deg C.

9. The thermal interface of claim 5 wherein the powder fill material is selected from the group consisting essentially of:
silver;
gold;
copper;
aluminum;
carbon;
graphite;
diamond;
a mixture of at least two of silver, gold, copper, aluminum, carbon, graphite and diamond; and
an alloy comprised of at least two of silver, gold, copper, aluminum, carbon, graphite and diamond.

10. A method of preparing a thermal interface comprising:
preparing a slurry comprising a liquid metal alloy of Gallium, Indium, tin and zinc and thermally conductive particles; and
impregnating and coating a conductive mesh with the slurry.

11. The method of claim 10, wherein preparing a slurry comprises preparing a slurry comprising a liquid metal alloy of 61% Gallium, 25% Indium, 13% tin and 1% zinc.

12. The method of claim 11 wherein the thermally conductive particles are provided as silver particles having a size of approximately 25 μm and the slurry comprises 40% by volume of the silver particles.

13. The method of claim 12 wherein impregnating and coating a conductive mesh comprises impregnating and coating a copper mesh having approximately 100 wires per inch with each of the wires having a diameter of approximately 0.0022 inches.

14. The method of claim 12 wherein impregnating the conductive mesh comprises adding the conductive mesh to a vessel having the slurry disposed therein; and
rubbing the slurry into the conductive mesh until the conductive mesh is impregnated and coated with the slurry; and
removing excess slurry.

15. A method of preparing a slurry comprising:
placing a predetermined amount of a liquid metal alloy into a mixing vessel;
adding thermally conductive particles to said liquid metal alloy; and
mixing the liquid metal alloy with the thermally conductive particles until the thermally conductive particles have been absorbed by the liquid metal alloy to provide the slurry having a non-eutectic solder joint.

16. The method of claim 15 wherein placing a predetermined amount of a liquid metal alloy into a mixing vessel comprises placing, a liquid metal alloy comprising 61% Gallium, 25% Indium, 13% tin and 1% zinc into a mixing vessel.

17. The method of claim 16 wherein adding thermally conductive particles to said liquid metal alloy comprises adding approximately 40% by volume of silver particles to said liquid metal alloy, with the silver particles having a size of approximately 25 μm.
